(19) United States
(12) Patent Application Publication
(10) Pub. No.: US 2004/0086787 A1
(43) Pub. Date: May 6, 2004

(54) Alternating aperture phase shift photomask having plasma etched isotropic quartz features

(76) Inventors: Nabila Lehachi Waheed, Allen, TX (US); William Otis Walden, Austin, TX (US); Patrick Martin, Dallas, TX (US)

Correspondence Address: Charles R. Macedo, Esq., Amster, Rothstein & Ebenstein, 90 Park Avenue, New York, NY, 10016, US

(21) Appl. No.: 10/288,736

(22) Filed: Nov. 5, 2002

(51) Int. Cl. G03F 9/00; G03F 7/00

(52) U.S. Cl. 430/5; 430/313; 430/396

(57) ABSTRACT

The present invention generally relates to optical lithography and more particularly relates to the fabrication of transparent or semitransparent phase shifting masks used in the manufacture of semiconductor devices. More particularly, the present invention implements a method for modifying anisotropically etched features on conventional alternating aperture phase shift masks (“aaPSMs”) using an isotropic plasma quartz etch process, which involves three processing stages: (1) defining the opaque region (e.g., chrome) using a chlorine-based decoupled plasma process; (2) forming an alternating anisotropic phase shift feature to a specific predetermined depth through the use of a decoupled plasma source with a fluorine etchant; and (3) changing the plasma conditions by interrupting the bias power applied across the mask and etching strictly in the inductively coupled plasma mode. These three processing stages achieve an isotropic undercutting of opaque layers which define the aaPSM.

### FIELD OF THE INVENTION

The present invention generally relates to optical lithography and more particularly relates to the fabrication of transparent or semitransparent phase shifting masks used in the manufacture of semiconductor devices. In particular, the present invention implements a method for modifying anisotropically etched features on conventional alternating aperture phase shift masks (“aaPSMs”) by using an isotropic plasma quartz etch process. This process forms an isotropic undercutting of opaque layers that define the aaPSM of the present invention.

### BACKGROUND OF THE INVENTION

Photomasks are high precision plates containing microscopic images of electronic circuits. Photomasks are typically made from flat pieces of material that are substantially transparent, such as quartz or glass, with an opaque layer, such as chrome, on one side. Etched in the opaque layer (e.g., chrome) of the mask is a pattern corresponding to a portion of an electronic circuit design. A variety of different photomasks, including for example, aaPSMs, embedded attenuated phase shift masks and binary chrome-on-glass masks, are used in semiconductor processing to transfer these patterns onto a semiconductor wafer or other type of wafer.

As shown in FIGS. 1a and 1b, to create an image on a semiconductor wafer 20, a photomask 9 is interposed between the semiconductor wafer 20 (which includes a layer of photosensitive material) and an optical system 22. Energy generated by an energy source 23, commonly referred to as a Stepper, is inhibited from passing through opaque areas of the photomask 9. Likewise, energy from the Stepper passes through the substantially transparent portions of the photomask 9, thereby projecting a diffraction limited, latent image of the pattern on the photomask onto the semiconductor wafer 20. In this regard, the energy generated by the Stepper causes a reaction in the photosensitive material on the semiconductor wafer such that the solubility of the photosensitive material is changed in areas exposed to the energy. Thereafter, the photosensitive material (either exposed or unexposed) is removed from the semiconductor wafer 20, depending upon the type of photolithographic process being used. For example, where a positive photolithographic process is implemented, the exposed photosensitive material becomes soluble and is removed. By contrast, where a negative photolithographic process is used, the exposed photosensitive material becomes insoluble and the unexposed, soluble photosensitive material is removed. After the appropriate photosensitive material is removed, a pattern corresponding to the photomask 9 appears on the semiconductor wafer 20. Thereafter, the semiconductor wafer 20 can be used for deposition, etching, and/or ion implantation processes in any combination to form an integrated circuit.

As circuit designs have become increasingly complex, semiconductor manufacturing processes have become more sophisticated to meet the requirements of these complex designs. In this regard, devices on semiconductor wafers have continued to shrink while circuit densities have continued to increase. This has resulted in an increased use of devices packed with smaller feature sizes, narrower widths and decreased spacing between interconnecting lines. For photolithographic processes, resolution and depth of focus (DoF) are important parameters in obtaining high fidelity of pattern reproduction from mask to wafer. However, as feature sizes continue to decrease, the devices' sensitivity to the varying exposure tool wavelengths (e.g., 248 nm, 193 nm, 157 nm, 13 nm, etc.) used to write images on a semiconductor wafer has increased, thereby making it more and more difficult to write to an accurate image on the semiconductor wafer. In this regard, as feature sizes continue to decrease, light diffraction effects in the mask are exacerbated, thereby increasing the likelihood that defects will manifest in a pattern written on a semiconductor wafer. Accordingly, it has become necessary to develop new methods to minimize the problems associated with these smaller feature sizes.

One known method for increasing resolution in smaller feature sizes involves the use of shorter exposure wavelengths (e.g., 248 nm, 193 nm, 157 nm, 13 nm, etc.). Shorter exposure wavelengths, however, typically result in a shallower DoF in conventional binary chrome-on-glass (COG) masks having smaller feature sizes. In this regard, when the feature size is smaller than the exposure tool wavelength, binary COG masks become diffraction limited, thereby making it difficult, if not impossible, to write an accurate image on the semiconductor wafer. Accordingly, phase shifting masks (“PSMs”) have been used to overcome this problem. In this regard, PSMs are known to have properties which permit high resolution while maintaining a sufficient DoF. More particularly, a PSM reduces the diffraction limitation ordinarily associated with a binary COG mask by passing light through substantially transparent areas (e.g., glass or quartz) which have either different thickness and/or different refractive indices than an ordinary binary COG mask. As a result, destructive interference is created in regions on the target semiconductor wafer that are designed to see no exposure. Thus, by reducing the impact of diffraction through phase shifting, the overall printability of an image is vastly improved such that the minimum width of a pattern resolved by using a PSM is approximately half the width of a pattern resolved in using an ordinary binary COG mask.

Various types of PSMs have been developed and are known in the art, including aaPSMs. FIGS. 2a-b illustrate an example of a conventional aaPSM 10. An aaPSM is typically comprised of a layer of opaque material and a substantially transparent substrate which is etched on one side of the opaque features, while not etched on the other side (i.e., etching of the transparent substrate occurs in alternating locations in the substantially transparent substrate). More particularly, as shown in FIGS. 2a-b, the aaPSM 10 includes a substantially transparent layer (e.g., quartz) and an opaque layer (e.g., chrome). The opaque layer is etched to form opaque regions 15 and alternating substantially transparent regions 13, as shown in FIG. 2b. The substantially transparent regions 13 are further etched such that the aaPSM 10 has recesses 14 in the substantially transparent layer. In other words, the aaPSM 10 has substantially transparent regions 13 (which are un-etched) that alternate with etched recesses 14 between each opaque region 15, as shown in FIGS. 2a-b. The effect of this structure when placed in a Stepper is to create light intensity of alternating polarity and 180° out of phase, as shown in FIG. 2c. This alternating polarity forces energy transmitted from the Stepper to go to zero at opaque regions 15 while maintaining the same transmission of light at the alternating transparent regions 13 and recesses 14. Since the photoresist layer on the semiconductor wafer is insensitive to the phase of the exposed light, the positive and negative exposed regions appear the same, while the zero region in between is clearly delineated. Thus, a sharper contrast between light (i.e., transparent) and dark (i.e., opaque) regions in the resulting photoresist layer of a semiconductor is obtained, thereby making it possible to etch a more accurate image onto the semiconductor wafer.

FIGS. 2a-d also demonstrate how an aaPSM reduces diffraction and improves printability on semiconductor wafers. As shown in FIG. 2c, by alternating the etched substantially transparent regions with un-etched substantially transparent regions, it is possible to create alternating regions within the mask wherein transmission is the same. The most common type of aaPSM uses a subtractive etch, where an opaque feature 15 is bounded by two transmissive quartz features (i.e., substantially transparent region 13 and recess 14). Thus, when energy is passed through the substantially transparent regions 13, there is a high transmission of light through such regions. Likewise, the etched substantially transparent regions 14 are 180° out of phase with the un-etched substantially transparent region 13. As a result, refraction is reduced through this region. In this regard, in recesses 14, the following equation is satisfied:

d=λ/2(n−1)

where d is film thickness, n is refractive index at exposure wavelength, λ is exposure wavelength. Thus, it is possible to etch smaller features in a semiconductor wafer and use shorter exposure wavelengths.

It is known in the art of photomask design to etch highly anisotropic features (i.e., features etched more in one direction than in other directions) in aaPSMs, as shown in FIGS. 3a and 4. Anisotropic features are typically formed by using a plasma reactor. In particular, it is known to use a fluorocarbon or hydrofluorocarbon etching gas and apply a radio frequency (“RF”) bias to the pedestal supporting the photomask. The RF bias creates a direct current (“DC”) bias in the plasma adjacent to the mask. The DC bias accelerates the ions towards the mask and the resulting etch is highly anisotropic with nearly vertical sidewalls. In addition to plasma etching techniques, wet etching technique can be used to undercut features in the phase shift mask, as shown in FIG. 3b.

However, anisotropic features produce a waveguide effect during wafer printing which induces an aerial image intensity imbalance through focus on the wafer, as shown in FIGS. 3a-3h. For example, as shown in FIGS. 3c, 3e and 3g, aerial image intensity imbalance caused by aaPSM quartz features having sidewalls that have been anisotropically etched can result in a relative difference of exposure intensity at the wafer plane if the stepper is not in perfect focus. For example, where the stepper is −0.4 μm out of focus, the aerial image intensity of the energy transmitted through the aaPSM of FIG. 3a is approximately 2.8 a.u. for shallow etched features and 2.2 a.u. for deep etched features, and approximately 3.5 a.u. for shallow etched features and 3.0 a.u. for deep etched features when in perfect focus (i.e., 0.0 μm). Any imbalance in aerial image intensity will result in an inaccurate image being written on the semiconductor wafer. In this regard, since the threshold energy needed to activate photoresist on the wafer is constant, any dissimilarity in intensity for adjacent features will produce a different final critical dimension for adjacent features on the wafer. As a result, the focus latitude required to obtain good pattern transfer from mask to wafer is reduced. This impact on printability due to the waveguide effect has been shown in the prior art to be effectively eliminated by isotropically etching (i.e., etching in one direction) quartz trench features which were formed by anisotropic etching methods.

A known method for reducing aerial image intensity imbalance is to create isotropic trenches in conventional aaPSMs by utilizing: a dry plasma etching step to form an anisotropic trench; and thereafter, a wet hydrofluoric acid (HF) dip, as described in U.S. Patent Application Publication No. 2001/0044056 Al to isotropically etch the anisotropic trench. As shown in FIGS. 3a, 3c, 3e and 3g, the aerial image intensity imbalance in this type of aaPSM is significantly reduced when the stepper is out of focus. Although useful for reducing aerial image intensity imbalance, the known methods (e.g., a dry etch followed by a wet etch) has significant drawbacks which have deterred photomask manufacturers from implementing this otherwise useful aaPSM. In particular, HF is known to be a very toxic and corrosive chemical which is hazardous to handle in a production environment. Thus, any isotropic method that can achieve the same results without resorting to the use of this hazardous material is preferred. Additionally, HF requires separate processing equipment, and thus, makes the overall manufacture of photomasks more expensive and time consuming. Additionally, since HF is hazardous to the environment, it is necessary to dispose of it in a proper and lawful manner, which can also be costly and burdensome. Furthermore, the wet etch process is purely isotropic in nature and cannot be tuned to prevent excessive undercut and chrome liftoff. Excessive undercut and chrome liftoff is disadvantageous because it can cause defects. Thus, any process which permits greater latitude for adjusting the magnitude of undercut is need, especially where smaller feature sizes are used. An additional concern with respect to wet chemistry is the loading effects of dense to isolated patterned areas. In this regard, an isolated areas etch rates are effected by chemical dilution due to the extreme exposed areas, thereby making it difficult to control the etch time. Thus, wet etching techniques often result in excessive undercut in such exposed areas. Therefore, what is needed is an improved method for isotopically etching aaPSMs which avoids using hazardous materials and is tunable to avoid excessive undercut and chrome liftoff and can minimize loading effects.

It is an object of the present invention to provide an aaPSM for use in photolithography and for semiconductor fabrication to enhance resolution and depth of focus.

It is a further object of the present invention to provide an improved method for isotropically etching aaPSMs which does not utilize hazardous materials.

It is another object of the present invention to provide an improved method for isotropically etching aaPSMs in a tunable manner so as to avoid excessive undercut and chrome liftoff.

It is a further object of the present invention to provide an improved method for isotropically etching aaPSMs in a manner which minimizes loading effects.

It is another object of the present invention to solve the shortcomings of the prior art.

Other objects will become apparent from the foregoing description.

### SUMMARY OF THE INVENTION

It has now been found that the above and related objects of the present invention are obtained in the form of a method of modifying anisotropically etched features on conventional aaPSMs by using an isotropic plasma etch to create isotropic, substantially transparent trenches which undercut overlying opaque layers.

More particularly, the present invention implements a method for modifying anisotropically etched features on conventional alternating aperture phase shift masks (“aaPSMs”) using the following isotropic plasma quartz etch three stage process: (1) defining the opaque region (e.g., chrome) using a chlorine-based decoupled plasma process; (2) forming an alternating anisotropic phase shift feature to a specific predetermined depth through the use of a decoupled plasma source with a fluorine etchant; and (3) changing the plasma conditions by interrupting the bias power applied across the mask and etching strictly in the inductively coupled plasma mode. These three processing stages achieve an isotropic undercutting of opaque layers which define the aaPSM.

### BRIEF DESCRIPTION OF THE DRAWINGS

The above and related objects, features and advantages of the present invention will be more fully understood by reference to the following, detailed description of the preferred, albeit illustrative, embodiment of the present invention when taken in conjunction with the accompanying figures, wherein:

FIG. 1a shows the equipment which can be used to make a semiconductor device from the aaPSM of the present invention;

FIG. 1b is flow diagram showing an example of the process for making a semiconductor device;

FIG. 2a shows a top view of a conventional aaPSM;

FIG. 2b shows a corresponding side view of the conventional aaPSM shown in FIG. 2a;

FIG. 2c shows the corresponding transmission of light through etched and un-etched regions of the substantially transparent layer of the conventional aaPSM of FIGS. 2a and 2b;

FIG. 2d shows the corresponding regions in a semiconductor wafer onto which the light is transmitted from the aaPSM shown in FIGS. 2a and 2b;

FIG. 3a shows a side view of an anistropically etched aaPSM;

FIG. 3b shows a side view of an aaPSM having anisotropic trenches that have been isotropically undercut using wet etching techniques;

FIG. 3c shows the aerial image intensity of the aaPSM of FIG. 3a when the Stepper is in perfect focus;

FIG. 3d shows the aerial image intensity of the aaPSM of FIG. 3b when the Stepper is in perfect focus;

FIG. 3e shows the aerial image intensity of the aaPSM of FIG. 3a when the Stepper is out of focus;

FIG. 3f shows the aerial image intensity of the aaPSM of FIG. 3b when the Stepper is out of focus;

FIG. 3g is a graph showing the aerial image intensity for deep and shallow etched trenches of the aaPSM of FIG. 3a at different focus levels;

FIG. 3h is a graph showing the aerial image intensity for deep and shallow etched trenches of the aaPSM of FIG. 3b at different focus levels;

FIG. 4a is a side view of a conventional aaPSM having an anisotropic trench;

FIG. 4b is a side view of a conventional aaPSM having an anisotropic trench which has been isotropically etched to undercut the opaque layer of the mask;

FIG. 5 shows a cross-sectional view of an anisotropic quartz feature in a conventional aaPSM;

FIG. 6 shows a cross-sectional view of a trench in an aaPSM which has been etched using both isotropic and anisotropic etching methods;

FIG. 7 is a flow diagram showing the steps required for producing the aaPSM of the present invention; and

FIG. 8 shows a cross-sectional view of a decoupled plasma source chamber used to etch the aaPSM of the present invention.

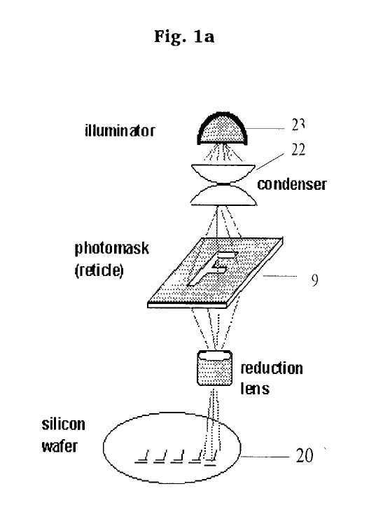

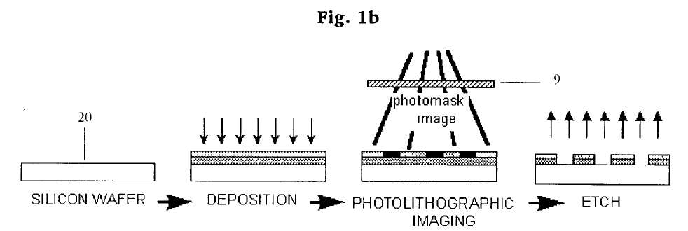

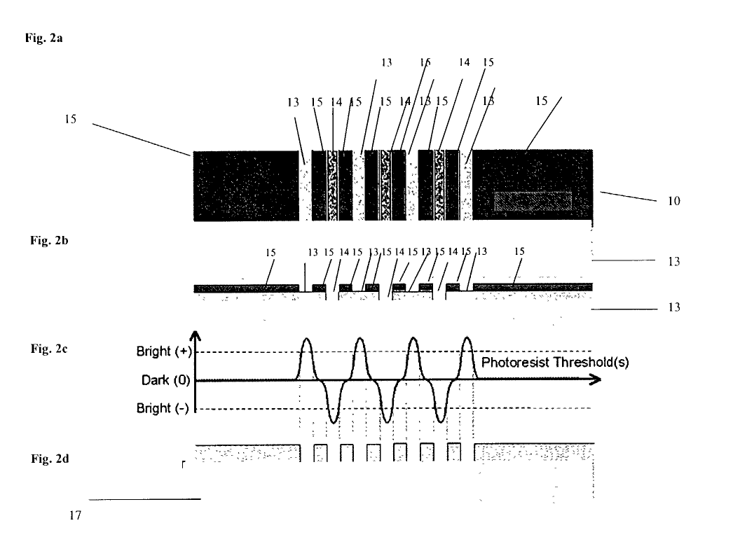

### DETAILED DESCRIPTION OF THE INVENTION

The present invention relates to a method for modifying anisotropically etched features of traditional aaPSMs by using an isotropic plasma (i.e., dry) etch to create substantially transparent (e.g., quartz) trenches that undercut overlying opaque (e.g., chrome) layers. By using dry etch techniques, etch rates can be optimized through the control of residence time (e.g., through control of pressure, chemistry and passivation of the substrate). In other words, unlike the prior art, it is possible to isotropically etch an aaPSM in a tunable manner so as to avoid excessive undercut and chrome lift off. Additionally, these dry etch techniques are environmentally safe, unlike techniques used in the prior art.

More particularly, one embodiment of the present invention includes a process for creating isotropic features in the substantially transparent layer of an aaPSM, wherein three dry etch-processing stages are used to form such features. Generally speaking, these three stages can be summarized as follows: (1) defining the opaque region (e.g., chrome) using a chlorine-based decoupled plasma process (e.g., Cl/O₂/He); (2) forming an alternating anisotropic phase shift feature to a specific predetermined depth through the use of a decoupled plasma source with a fluorine etchant; and (3) changing the plasma conditions by interrupting the bias power applied across the mask to change the plasma conditions and etching strictly in the Inductively Coupled Plasma (“ICP”) mode. This nondirectional plasma succeeds in isotropically undercutting the chrome in a tunable manner. It should be noted that the second and third processing stages could be performed in reverse order. They may also be performed either in the same etching apparatus or different etching apparatuses. The details involved in each of these processing stages are now described.

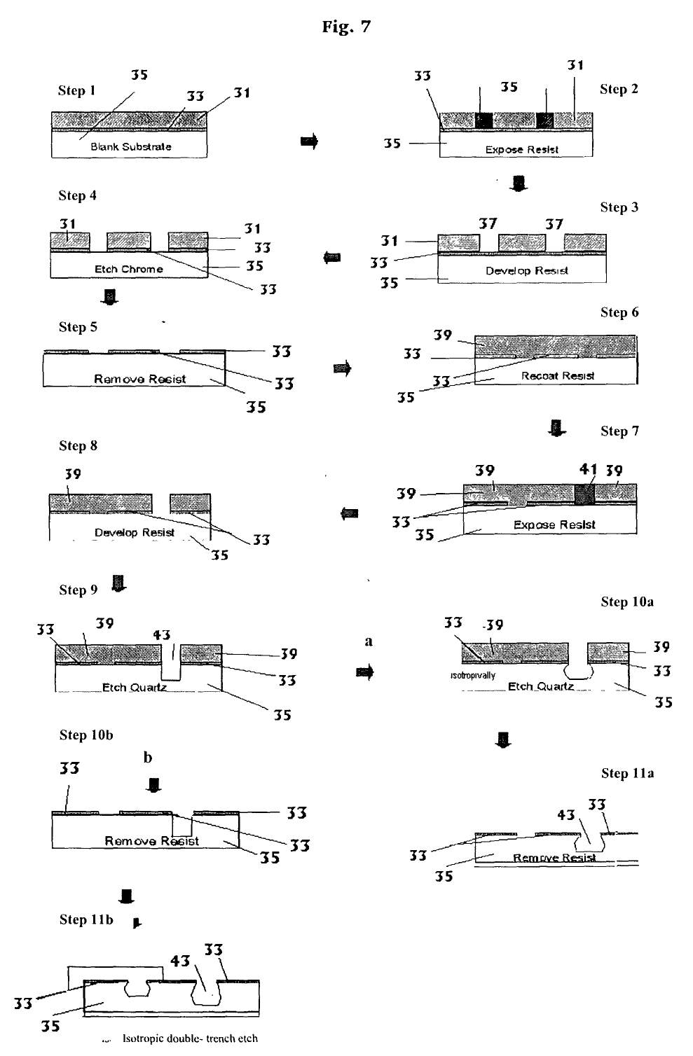

The first processing stage of the present invention (i.e., defining the opaque region in the mask) involves several steps. Referring to FIG. 7, a blank photomask 30 comprising a photosensitive resist layer 31, opaque layer 33 and a substantially transparent layer 35 is provided, Step 1. Preferably, the opaque layer 33 is chrome and the substantially transparent layer 35 is quartz. However, these layers may be made of other suitable materials. Additionally, the opaque layer 33 may additionally include an anti-reflective layer, such as chrome oxide. Next, predefined areas 35 in the photosensitive resist layer 31 of the blank photomask are exposed to an energy source (e.g., a light source), Step 2. Thereafter, the exposed resist 35 is developed (i.e., removed), thereby forming a recess 37 in the photosensitive resist layer 31, Step 3. Next, the portions of the opaque layer 33 underlying the recesses 37 are removed by a dry etch process, Step 4. In a preferred embodiment, a chlorine-based decoupled plasma etching process (e.g., Cl/O₂/He) is used to remove these opaque portions. Thereafter, the remaining photosensitive resist overlying the undeveloped portions of the opaque layer 33 is removed, Step 5. As a result, the un-etched portions of the opaque layer 33 serve to block the exposure light during wafer printing, whereas the portions of the opaque layer which have been etched away define the region of the substantially transparent layer which allows exposure light from the Stepper to pass through. In essence, the first processing stage of the method of the present invention is used to form a conventional binary photomask by patterning an opaque layer using photo resist and dry etch methods. It should be noted, however, the wet chemistry process could also be used to etch the opaque layers.

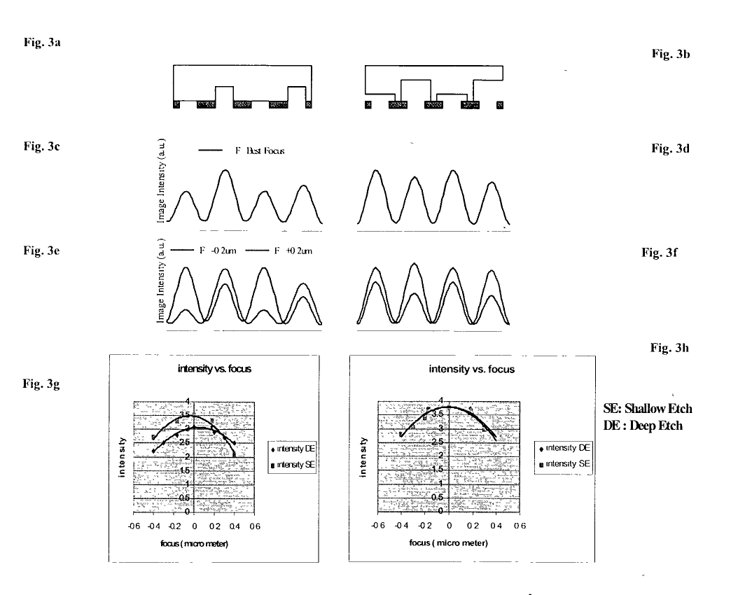

Next, the second processing stage (i.e., the formation of alternating anisotropic phase-shift features in the substantially transparent layer) of the method of the present invention is commenced. The second processing stage also requires several steps. In particular, after Step 5 has been completed, the remaining portions of the opaque layer 33 and the uncovered portions of the substantially transparent layer 35 are re-coated with photosensitive resist 39, Step 6. Predefined areas 41 in the photo resist layer 39 of the photomask are exposed to an energy source (e.g., a light source), Step 7. One example of a light source which can be used is an imaging source such as a laser or electron beam. In one embodiment, the laser source which is used operates at 365 nm, however, the present invention is not limited to this particular laser source and will work with a variety of different image sources as discussed herein. In this regard, these predefined areas are defined by exposing, in an alternating manner, regions of the substantially transparent layer 35 not covered by opaque material. However, the present invention is not limited to PSMs which have alternating etched regions. It may also be used in any PSM which has etched regions, whether alternating or not. Next, the exposed areas 41 of the photo resist layer 39 are developed (i.e., removed), Step 8. Thereafter, the portions of the substantially transparent layer that are no longer covered by photosensitive resist material 39 (or opaque material 33) are anisotropically etched to a specified depth, Step 9. As a result, a phase shifted, transmissive vertical trench 43 is formed in the substantially transparent layer 35, as shown in FIG. 4a.

In a preferred embodiment of the present invention, a decoupled plasma source (“DPS”) with a fluorine etchant is used to form the anisotropic trench 43. One example of a DPS includes the Systems' Tetra™, Centura II. It should be noted that the portions of the substantially transparent layer 35 which are covered by the photosensitive resist material 39, by contrast, are not etched. In this processing stage, the trench 43 has a relative depth that is sufficiently less than 180 degrees of the exposure wavelength as compared to the zero degree transmissive layers described in the first processing stage. In this regard, the trench 43 should have a depth which permits the third processing stage described below to achieve a total depth of the trench 43 which is 180 degrees of the exposure wavelength as compared to the zero degree transmissive layers. It should be noted that the trench 43 may alternatively have a depth which permits the third processing stage described below to achieve a total depth of the trench 43 which is a multiple of 180 degrees phase shift wherein the following equation is satisfied: d=(n*360 degrees)+180 degrees, where d is the final trench depth and n is an integer.

Next, the third processing stage is commenced. In particular, the trench 43 is isotropically dry etched, Step 10a, and the remaining photosensitive resist 30 is removed, Step 11a. As a result, the isotropic etching methods undercut the opaque layers 33 next to the trench 43, as shown in FIG. 4b. The final depth of the trench 43 should be approximately 180 degrees (or a multiple thereof which satisfies the equation: d=(n*360 degrees)+180 degrees) out of phase with the exposure wavelength as compared to the zero degree transmissive layers described in the first processing stage. In an alternative embodiment, a dual trench can be formed in the substrate by the methods described herein. In this regard, subsequent to performing Step 9, the remaining photosensitive resist 39 is removed, Step 10b, and both the trench 33 and substantially transparent layer(s) 35 not covered by the opaque layer(s) 33 are isotropically etched to form a double trench, wherein Cr is used as an etch stop layer instead of photoresist.

Preferably, the dry etch method of the present invention is performed by changing the plasma conditions used to etch the trench 43 in the second processing stage. In particular, the bias power applied across the mask is interrupted (i.e., cut off) and the trench 43 is etched strictly in an inductively coupled plasma (“ICP”) mode. Under these conditions, the plasma becomes nondirectional, thus permitting lateral movement of the plasma toward the sidewall of the substantially transparent layer in the etched region of the aaPSM being processed. As a result, this nondirectional plasma succeeds in isotropically undercutting the opaque layers 33 next to the trench 43, as shown in FIG. 4b.

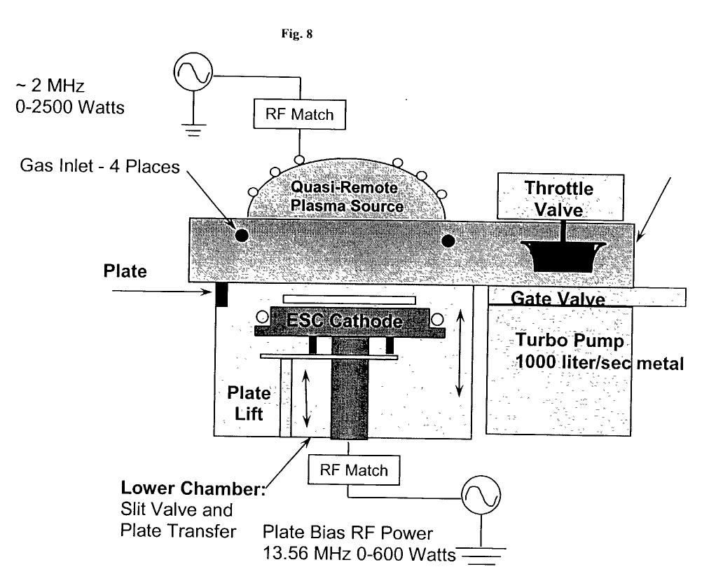

In one embodiment, the processing stages of the present invention are performed as follows. In the first processing stage, a conventional binary chrome on glass mask is formed in a blank photomask by patterning a chrome layer of a mask using the techniques described herein. In the second processing stage, an anisotropic trench 43 with a high aspect ratio (i.e., the ratio of trench depth to trench width) and small critical dimensions (“CDs”) is formed in uncovered portions of the substantially transparent layer using a DPS reactor of the type shown in FIG. 8. More particularly, the DPS reactor of FIG. 8 comprises two independent plasma sources: an ICP which is produced using an RF power inductive coil above the mask; and a secondary plasma source which is produced via an RF bias applied across the mask (which rests on a cathode pedestal). An example of such plasma source includes Systems' Tetra™, Centura II. In this embodiment, the following processing parameters and conditions listed in Table 1 were used to anisotropically etch the trench 43 in the aaPSM:

TABLE 1

| | |
|---|---|
| Pressure | 6 mTorr |
| Bias Power | 200 W |
| ICP Power | 100 W |
| Cathode Temp | 23 degrees |
| Wall Temp | 72 degrees |
| Dome temp | 80 degrees |
| C₂F₆ Flow | 25 sccm |
| O₂ Flow | 3 sccm |
| Etch Time | 143 sec |

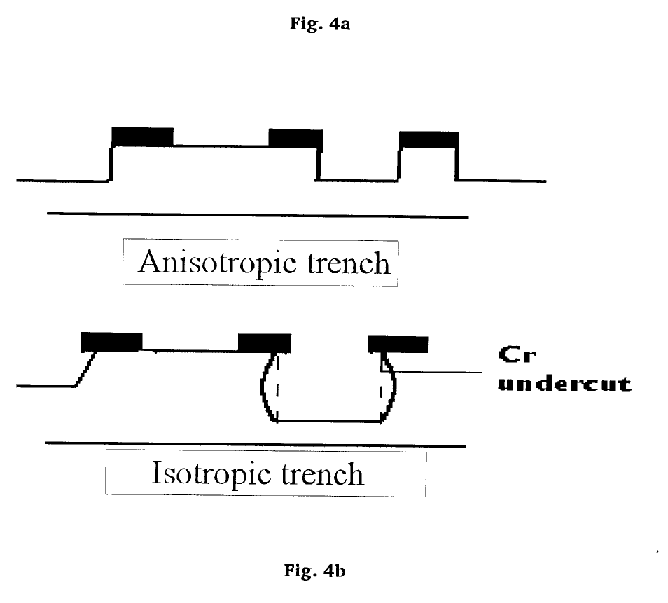

In this example, the anisotropic trench 43 was formed in the photomask, as shown in FIG. 5. It should be noted, however, that the anisotropic trench can be formed by other methods and parameters now known or herein after developed. In the third processing stage of this example, the bias power was removed and only the ICP was used to isotropically etch the trench 43 so as to undercut the opaque layer 33 next to the trench 43. In this example, the following processing parameters and conditions listed in Table 2 were used to isotropically etch the trench 43:

TABLE 2

| | | |
|---|---|---|
| Pressure | 25 | mTorr |
| Bias Power | 0 | W |
| ICP Power | 500 | W |
| Cathode Temp | 23 | degrees |
| Wall Temp | 72 | degree |
| Dome temp | 80 | degrees |
| Ar Flow | 10 | sccm |
| C₂F₆/SF₆ Flow | 40/15 | sccm |
| O₃ Flow | 3 | sccm |
| He Flow | 40 | sccm |
| Etch Time | 400 | sec |

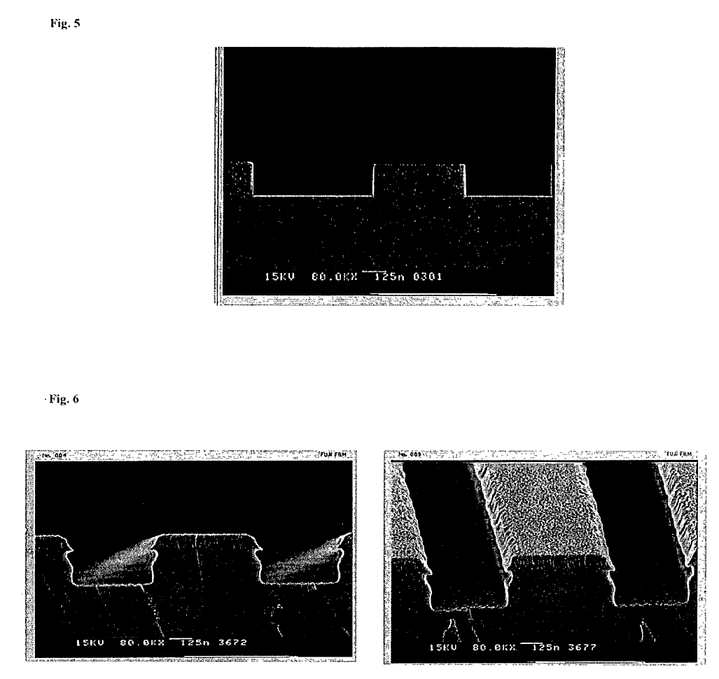

In this example, the isotropic etching process resulted in trench 43 undercutting the chrome layers next to the trench 43, as shown in FIG. 6. It should be noted, however, that the undercut in trench 43 can be formed by other dry etching methods and parameters now known or herein after developed.

Although certain specific embodiments of the present invention have been disclosed, it is noted that the present invention may be embodied in other forms without departing from the spirit or essential characteristics thereof. In this regard, it should be understood from the above description that to achieve the required 180 degrees phase shift in the aaPSM of the present invention, the second and third processing stages (i.e., an isotropic etch followed by an anisotropic etch) must result in the total desired depth relative to the alternating substantially transparent features. This can be achieved by processing the mask using the methods described above (e.g., by protecting the 0 degree substantially transparent feature with resist and etching the shifted quartz feature to a depth equivalent to 180 degrees with respect to the exposure wavelength), or by leaving the 0 phase unprotected so that it is etched simultaneously with the phase shifted feature, but still maintaining a 180 degree phase shift between the features. The latter method is commonly referred to as a “dual trench” and is also applicable to this invention. Additionally, the shape of the substantially transparent trench(es) (lateral-to-vertical ratio) can be varied by changing etch conditions and relative etch times for step 2 and 3. This allows for customization of the holes to prevent chrome liftoff upon moving to more dense and smaller critical dimensions. Furthermore, the processing stage 3 can be performed before processing stage 2 is so desired. Finally, it is noted that the method making the aaPSM of the present invention is not limited to the type of DPS described herein. In this regard, one or more DPS can be used to perform the steps of the present invention.

Now that the preferred embodiments of the present invention have been shown and described in detail, various modifications and improvements thereon will become readily apparent to those skilled in the art. The present embodiments are therefor to be considered in all respects as illustrative and not restrictive, the scope of the invention being indicated by the appended claims, and all changes that come within the meaning and range of equivalency of the claims are therefore intended to be embraced therein.

What is claimed is:

1. A method for forming isotropic regions in an alternating aperture phase shift mask comprising the steps of:
defining the opaque region of the mask;
forming an alternating anisotropic phase shift feature to a specific predetermined depth using dry etching techniques; and
forming an isotropic feature in said anisotropic phase feature using dry etch techniques.

2. The method of claim 1, wherein said alternating anisotropic phase shift feature is formed with a decoupled plasma source.

3. The method of claim 2, further comprising the steps of interrupting the bias power applied across the mask to change the plasma conditions and etching the phase shift feature in an inductively coupled plasma mode.

4. The method of claim 2, wherein a fluorine etchant is used with said decoupled plasma source to form said alternating anisotropic phase shift feature.

5. The method of claim 1, wherein said opaque region is defined by a chlorine-based decoupled plasma process.

6. The method of claim 1, wherein said opaque region comprises chrome.

7. The method of claim 6, wherein said opaque region further comprises an anti-reflective layer.

8. The method of claim 7, wherein said anti-reflective layer is chrome oxide.

9. The method of claim 1, wherein said phase shift feature comprises quartz.

10. The method of claim 1, wherein said step of defining said opaque region further comprises the steps of:
exposing photosensitive resist to an energy source;
removing said exposed photosensitive resist; and
removing the opaque region underlying said removed photosensitive resist, thereby exposing a substantially transparent region.

11. The method of claim 10, wherein said step of forming an anisotropic phase shift feature further comprises the steps of:
re-coating said opaque region and said substantially transparent region with a second coating of photosensitive resist;
exposing predefined areas of said second coating of photosensitive resist to said energy source; and
removing said exposed areas of said photosensitive resist.

12. The method of claim 2, wherein said decoupled plasma source generates an inductively coupled plasma a radio frequency coil above the mask and a secondary plasma source which produced by an radio frequency bias applied across the mask.

13. The method of claim 12, wherein said decoupled plasma source forms the anisotropic phase shift features by applying:
6 mTorr of pressure;
200 W of power;
100 W of inductively coupled plasma power;
23 degree cathode temperature;
72 degree wall temperature;
80 degree dome temperature;
25 sccm of C₂F₆ flow;
3 sccm of O₂ flow; and
143 seconds of etch time.

14. The method of claim 13, wherein said isotropic feature is formed by applying:
25 mTorr of pressure;
0 W of bias power;
500 W of inductively coupled plasma power;
23 degree cathode temperature; 72 degree wall temperature;
80 degree dome temperature;
10 sccm Ar flow;
40/15 sccm of C₂F₆/SF₆ flow;
3 sccm of 03 flow;
40 sccm of He flow; and
400 seconds of etch time.

15. The method of claim 1, wherein said isotropic feature is a dual trench feature.

16. An alternating aperture phase shift mask having an isotropic region made by the steps of:
defining the opaque region of the mask;
forming an alternating anisotropic phase shift feature to a specific predetermined depth using dry etching techniques; and
forming an isotropic feature in said anisotropic phase feature using dry etch techniques.

17. The mask of claim 16, wherein said alternating anisotropic phase shift feature is formed with a decoupled plasma source.

18. The mask of claim 17, further comprising the steps of interrupting the bias power applied across the mask to change the plasma conditions and etching the phase shift feature in an inductively coupled plasma mode.

19. The mask of claim 17, wherein a fluorine etchant is used with said decoupled plasma source to form said alternating anisotropic phase shift feature.

20. The mask of claim 16, wherein said opaque region is defined by a chlorine-based decoupled plasma process.

21. The mask of claim 16, wherein said opaque region comprises chrome.

22. The mask of claim 21, wherein said opaque region further comprises an anti-reflective layer.

23. The mask of claim 22, wherein said anti-reflective layer is chrome oxide.

24. The mask of claim 16, wherein said phase shift feature comprises quartz.

25. The mask of claim 16, wherein said step of defining said opaque region further comprises the steps of:
exposing photosensitive resist to an energy source;
removing said exposed photosensitive resist; and
removing the opaque region underlying said removed photosensitive resist, thereby exposing a substantially transparent region.

26. The mask of claim 25, wherein said step of forming an anisotropic phase shift feature further comprises the steps of:
re-coating said opaque region and said substantially transparent region with a second coating of photosensitive resist;
exposing predefined areas of said second coating of photosensitive resist to said energy source; and
removing said exposed areas of said photosensitive resist.

27. The mask of claim 17, wherein said decoupled plasma source generates an inductively coupled plasma a radio frequency coil above the mask and a secondary plasma source which produced by an radio frequency bias applied across the mask.

28. The mask of claim 27, wherein said decoupled plasma source forms the anisotropic phase shift features by applying:
6 mTorr of pressure;
200 W of power;
100 W of inductively coupled plasma power;
23 degree cathode temperature;
72 degree wall temperature;
80 degree dome temperature;
25 sccm of C₂F₆ flow;
3 sccm of O₂ flow; and
143 seconds of etch time.

29. The mask of claim 28, wherein said isotropic feature is formed by applying:
25 mTorr of pressure;
0 W of bias power;
500 W of inductively coupled plasma power;
23 degree cathode temperature;
72 degree wall temperature;
80 degree dome temperature;
10 sccm Ar flow;
40/15 sccm of C₂F₆/SF₆ flow;
3 sccm of O₃ flow;
40 sccm of He flow; and
400 seconds of etch time.

30. The mask of claim 16, wherein said isotropic feature is a dual trench feature.

31. A method for forming isotropic regions in an alternating aperture phase shift mask comprising the steps of:
defining the opaque region of the mask;
forming an alternating isotropic phase shift feature to a specific predetermined depth using dry etching techniques; and
forming an anisotropic feature in said isotropic phase feature using dry etch techniques.

32. The method of claim 31, wherein said isotropic phase shift feature is formed by interrupting a decoupled plasma source's bias power applied across the mask to change the plasma conditions and etching the phase shift feature in an inductively coupled plasma mode.

33. The method of claim 31, wherein said alternating anisotropic phase shift feature is formed with said decoupled plasma source.

34. The method of claim 33, wherein a fluorine etchant is used with said decoupled plasma source to form said alternating anisotropic phase shift feature.

35. The method of claim 31, wherein said opaque region is defined by a chlorine-based decoupled plasma process.

36. The method of claim 31, wherein said opaque region comprises chrome.

37. The method of claim 36, wherein said opaque region further comprises an anti-reflective layer.

38. The method of claim 37, wherein said anti-reflective layer is chrome oxide.

39. The method of claim 31, wherein said phase shift feature comprises quartz.

40. The method of claim 31, wherein said step of defining said opaque region further comprises the steps of:
exposing photosensitive resist to an energy source;
removing said exposed photosensitive resist; and
removing the opaque region underlying said removed photosensitive resist, thereby exposing a substantially transparent region.

41. The method of claim 40, wherein said step of forming an isotropic phase shift feature further comprises the steps of:
re-coating said opaque region and said substantially transparent region with a second coating of photosensitive resist;
exposing predefined areas of said second coating of photosensitive resist to said energy source; and
removing said exposed areas of said photosensitive resist.

42. The method of claim 33, wherein said decoupled plasma source generates an inductively coupled plasma using a radio frequency coil above the mask and a secondary plasma source which produced by an radio frequency bias applied across the mask.

43. The method of claim 42, wherein said decoupled plasma source forms the anisotropic phase shift features by applying:
6 mTorr of pressure;
200 W of power;
100 W of inductively coupled plasma power;
23 degree cathode temperature;
72 degree wall temperature;
80 degree dome temperature;
25 sccm of C₂F₆ flow;
3 sccm of O₂ flow; and
143 seconds of etch time.

44. The method of claim 13, wherein said isotropic feature is formed by applying:
25 mTorr of pressure;
0 W of bias power;
500 W of inductively coupled plasma power;
23 degree cathode temperature;
72 degree wall temperature;
80 degree dome temperature;
10 sccm Ar flow;
40/15 sccm of C₂F₆/SF₆ flow;
3 sccm of O₃ flow;
40 sccm of He flow; and
400 seconds of etch time.

45. The method of claim 31, wherein said isotropic feature is a dual trench feature.

46. An alternating aperture phase shift mask having an isotropic region made by the steps of:
defining the opaque region of the mask;
forming an alternating isotropic phase shift feature to a specific predetermined depth using dry etching techniques; and
forming an anisotropic feature in said isotropic phase feature using dry etch techniques.

47. The mask of claim 31, wherein said isotropic phase shift feature is formed by interrupting a decoupled plasma source's bias power applied across the mask to change the plasma conditions and etching the phase shift feature in an inductively coupled plasma mode.

48. The mask of claim 31, wherein said alternating anisotropic phase shift feature is formed with said decoupled plasma source.

49. The mask of claim 33, wherein a fluorine etchant is used with said decoupled plasma source to form said alternating anisotropic phase shift feature.

50. The mask of claim 31, wherein said opaque region is defined by a chlorine-based decoupled plasma process.

51. The mask of claim 31, wherein said opaque region comprises chrome.

52. The mask of claim 36, wherein said opaque region further comprises an anti-reflective layer.

53. The mask of claim 37, wherein said anti-reflective layer is chrome oxide.

54. The mask of claim 31, wherein said phase shift feature comprises quartz.

55. The mask of claim 31, wherein said step of defining said opaque region further comprises the steps of:
exposing photosensitive resist to an energy source;
removing said exposed photosensitive resist; and
removing the opaque region underlying said removed photosensitive resist, thereby exposing a substantially transparent region.

56. The mask of claim 40, wherein said step of forming an isotropic phase shift feature further comprises the steps of:
re-coating said opaque region and said substantially transparent region with a second coating of photosensitive resist;
exposing predefined areas of said second coating of photosensitive resist to said energy source; and
removing said exposed areas of said photosensitive resist.

57. The mask of claim 33, wherein said decoupled plasma source generates an inductively coupled plasma using a radio frequency coil above the mask and a secondary plasma source which produced by an radio frequency bias applied across the mask.

58. The mask of claim 42, wherein said decoupled plasma source forms the anisotropic phase shift features by applying:
6 mTorr of pressure;
200 W of power;
100 W of inductively coupled plasma power;
23 degree cathode temperature;
72 degree wall temperature;
80 degree dome temperature;
25 sccm of C₂F₆ flow;
3 sccm of O₂ flow; and
143 seconds of etch time.

59. The mask of claim 13, wherein said isotropic feature is formed by applying:
25 mTorr of pressure;
0 W of bias power;
500 W of inductively coupled plasma power;
23 degree cathode temperature;
72 degree wall temperature;
80 degree dome temperature;
10 sccm Ar flow;
40/15 sccm of C₂F₆/SF₆ flow;
3 sccm of O₃ flow;
40 sccm of He flow; and
400 seconds of etch time.

60. The mask of claim 1, wherein said isotropic feature is a dual trench feature.

61. A method for manufacturing a semiconductor comprising the steps of:
interposing a finished alternating aperture phase shift mask, having substantially transparent areas, between a semiconductor wafer and an energy source;
transmitting energy generated by said energy source through said substantially transparent areas of said finished mask to said semiconductor wafer; and
etching an image, corresponding to said substantially transparent areas of said finished photomask, on said semiconductor wafer, wherein said finished mask is made by defining the opaque region of the mask;
forming an alternating anisotropic phase shift feature to a specific predetermined depth using dry etching techniques; and
forming an isotropic feature in said anisotropic phase feature using dry etch techniques.

62. The method of claim 61, wherein said alternating anisotropic phase shift feature is formed with a decoupled plasma source.

63. The method of claim 62, further comprising the steps of interrupting the bias power applied across the mask to change the plasma conditions and etching the phase shift feature in an inductively coupled plasma mode.

64. The method of claim 62, wherein a fluorine etchant is used with said decoupled plasma source to form said alternating anisotropic phase shift feature.

65. The method of claim 61, wherein said opaque region is defined by a chlorine-based decoupled plasma process.

66. The method of claim 61, wherein said opaque region comprises chrome.

67. The method of claim 66, wherein said opaque region further comprises an anti-reflective layer.

68. The method of claim 67, wherein said anti-reflective layer is chrome oxide.

69. The method of claim 61, wherein said phase shift feature comprises quartz.

70. The method of claim 61, wherein said step of defining said opaque region further comprises the steps of:
exposing photosensitive resist to an energy source;
removing said exposed photosensitive resist; and
removing the opaque region underlying said removed photosensitive resist, thereby exposing a substantially transparent region.

71. The method of claim 70, wherein said step of forming an anisotropic phase shift feature further comprises the steps of:
re-coating said opaque region and said substantially transparent region with a second coating of photosensitive resist;
exposing predefined areas of said second coating of photosensitive resist to said energy source; and
removing said exposed areas of said photosensitive resist.

72. The method of claim 62, wherein said decoupled plasma source generates an inductively coupled plasma a radio frequency coil above the mask and a secondary plasma source which produced by an radio frequency bias applied across the mask.

73. The method of claim 72, wherein said decoupled plasma source forms the anisotropic phase shift features by applying:
6 mTorr of pressure;
200 W of power;
100 W of inductively coupled plasma power;
23 degree cathode temperature;
72 degree wall temperature;
80 degree dome temperature;
25 sccm of C₂F₆ flow;
3 sccm of O₂ flow; and
143 seconds of etch time.

74. The method of claim 73, wherein said isotropic feature is formed by applying:
25 mTorr of pressure;
0 W of bias power;
500 W of inductively coupled plasma power;
23 degree cathode temperature;
72 degree wall temperature;
80 degree dome temperature;
10 sccm Ar flow;
40/15 sccm of C₂F₆/SF₆ flow;
3 sccm of O₃ flow;
40 sccm of He flow; and
400 seconds of etch time.

75. The method of claim 61, wherein said isotropic feature is a dual trench feature.

76. A method for manufacturing a semiconductor comprising the steps of:
interposing a finished alternating aperture phase shift mask, having substantially transparent areas, between a semiconductor wafer and an energy source;
transmitting energy generated by said energy source through said substantially transparent areas of said finished mask to said semiconductor wafer; and
etching an image, corresponding to said substantially transparent areas of said finished photomask, on said semiconductor wafer, wherein said finished mask is made by defining the opaque region of the mask;
forming an alternating isotropic phase shift feature to a specific predetermined depth using dry etching techniques; and
forming an anisotropic feature in said isotropic phase feature using dry etch techniques.

77. The method of claim 76, wherein said isotropic phase shift feature is formed by interrupting a decoupled plasma source's bias power applied across the mask to change the plasma conditions and etching the phase shift feature in an inductively coupled plasma mode.

78. The method of claim 77, wherein said alternating anisotropic phase shift feature is formed with said decoupled plasma source.

79. The method of claim 78, wherein a fluorine etchant is used with said decoupled plasma source to form said alternating anisotropic phase shift feature.

80. The method of claim 76, wherein said opaque region is defined by a chlorine-based decoupled plasma process.

81. The method of claim 76, wherein said opaque region comprises chrome.

82. The method of claim 81, wherein said opaque region further comprises an anti-reflective layer.

83. The method of claim 82, wherein said anti-reflective layer is chrome oxide.

84. The method of claim 76, wherein said phase shift feature comprises quartz.

85. The method of claim 76, wherein said step of defining said opaque region further comprises the steps of:
exposing photosensitive resist to an energy source;
removing said exposed photosensitive resist; and
removing the opaque region underlying said removed photosensitive resist, thereby exposing a substantially transparent region.

86. The method of claim 85, wherein said step of forming an isotropic phase shift feature further comprises the steps of:
re-coating said opaque region and said substantially transparent region with a second coating of photosensitive resist;
exposing predefined areas of said second coating of photosensitive resist to said energy source; and
removing said exposed areas of said photosensitive resist.

87. The method of claim 78, wherein said decoupled plasma source generates an inductively coupled plasma using a radio frequency coil above the mask and a secondary plasma source which produced by an radio frequency bias applied across the mask.

88. The method of claim 87, wherein said decoupled plasma source forms the anisotropic phase shift features by applying:
6 mTorr of pressure;
200 W of power;
100 W of inductively coupled plasma power;
23 degree cathode temperature;
72 degree wall temperature;
80 degree dome temperature;
25 sccm of C₂F₆ flow;
3 sccm of O₂ flow; and
143 seconds of etch time.

89. The method of claim 88, wherein said isotropic feature is formed by applying:
25 mTorr of pressure;
0 W of bias power;
500 W of inductively coupled plasma power;
23 degree cathode temperature;
72 degree wall temperature;
80 degree dome temperature;
10 sccm Ar flow;
40/15 sccm of C₂F₆/SF₆ flow;
3 sccm of O₃ flow;
40 sccm of He flow; and
400 seconds of etch time.

90. The method of claim 76, wherein said isotropic feature is a dual trench feature.
